(19) United States
(12) Patent Application Publication
(10) Pub. No.: US 2019/0253928 A1
(43) Pub. Date: Aug. 15, 2019

(54) METHOD FOR TRANSMITTING INFORMATION

(71) Applicant: DIEHL METERING SYSTEMS GMBH, NUERNBERG (DE)

(72) Inventors: HRISTO PETKOV, NUERNBERG (DE); THOMAS LAUTENBACHER, ERLANGEN (DE); THOMAS KAUPPERT, NUERNBERG (DE); KLAUS GOTTSCHALK, WINKELHAID (DE)

(21) Appl. No.: 16/391,790

(22) Filed: Apr. 23, 2019

Related U.S. Application Data
(63) Continuation of application No. PCT/EP2017/001243, filed on Oct. 24, 2017.

(30) Foreign Application Priority Data
Nov. 16, 2016 (DE) 102016013654.5

(51) Int. Cl. H04W 28/06; H04L 1/00; H03M 13/09

(52) U.S. Cl. CPC H04W 28/065; H04L 1/0042; H03M 13/096; H04L 1/0061

(57) ABSTRACT

In the repeated transmission of information in the form of a coded packet from a transmitter via a radio link to a receiver, an interference-free receive packet is quickly available if interference-free subpackets are assembled from the packet as subpackets of the interference-free receive packet. For this purpose, subpackets of successively received and temporarily stored packets assigned to one another can be compared with one another and, in the event of a match, can be inserted in a gap-filling manner into the received packet. Alternatively, the successive packets are already divided in each case at the transmitting end into subpackets provided with error detection codes, the subpackets being incorporated into the received packet as soon as they have been correctly received in a packet.

### CROSS-REFERENCE TO RELATED APPLICATION

This is a continuation application, under 35 U.S.C. § 120, of copending international application No. PCT/EP2017/001243, filed Oct. 24, 2017, which designated the United States; this application also claims the priority, under 35 U.S.C. § 119, of German patent application No. DE 10 2016 013 654.5, filed Nov. 16, 2016; the prior applications are herewith incorporated by reference in their entirety.

### BACKGROUND OF THE INVENTION

### Field of the Invention

The invention relates to a method according to the preamble of the independent patent claim.

The information contains coded messages, referred to below as packets, for example for the wireless remote control of household installations such as heating, local lighting, movement of blinds and shutters or locking of garden gates and garage doors; but also for the wireless transmission of consumption measured values (in particular for gas, water, heat or power) from individual metering points to a common receiver memory (also referred to as a concentrator).

Packets of this type having a predefined length are transmitted identically multiple times in succession and are temporarily stored in a receiver, i.e., in particular, in the concentrator, in order to compare the successive packets with one another. If a plurality of the packets matches one another, they are deemed to be correct as a result of interference-free information transmission. However, even if only one bit deviates from the bit value at the same position in the previously received packet, all packets hitherto temporarily stored with this measured value are rejected as unsafe; and a further receive sequence of at least two complete packets must be awaited and temporarily stored to check for matching.

On the chronically overloaded publicly accessible radio channels in the ISM bands, the probability that a single temporary storage cycle of this type will already result in a correctly received, i.e. interference-free, receive packet is low; and the probability decreases with the length of the packets, i.e. the possibility of the interference environment introducing a bit error into the packet during the radio transmission. The need for the constant repetition of the radio transmission of a packet results not only in the lengthening of the period of time until the interference-free reception of a complete packet, but also imposes a substantial burden on the battery in the metering point transmitter and an additional load on the transmission channel.

In recognition of these factors, the technical object of the present invention is to speed up the determination of error-free transmission of packets and thereby enable a reduction of the burden on the transmitting power source and also the channel occupancy.

### SUMMARY OF THE INVENTION

This object is achieved according to the invention by the essential features indicated in the main claim. The packets are accordingly no longer checked in their entirety for matching in the receive memory following correct transmission, but instead each packet is checked on a subpacket basis according to the invention.

According to the invention, successively received packets can in each case be divided into subpackets for this purpose; and the interference-free receive packet is assembled in a gap-filling manner from matching, i.e. correctly received, subpackets. Alternatively, the packet containing the information is already divided into subpackets which are then transmitted in each case with an error detection code; and the interference-free receive packet is assembled in a gap-filling manner from the consequently correctly received subpackets.

The subpackets do not all need to have identical lengths; instead, the subpacket lengths can vary statically or dynamically over the length of their packet. It must only be ensured that at least two packet repetitions have the same subpacket divisions as one another if the correctness of this specific subpacket is to be inferred at the receiving end from matching repeated subpackets.

If a transmission error occurs, an entire packet is therefore no longer immediately rejected, but at most currently incorrectly received subpackets are rejected; the complete, ultimately interference-free, receive packet is assembled from the assembly of correctly received subpackets in the concentrator or similar buffer memory.

The subpackets from which a packet is compiled are invariably shorter than the complete packet. The probability of individual subpackets being incorrectly received is therefore much lower than compared with the packet length as a whole. The interference-free receive packet compiled from the interference-free subpackets is therefore available more quickly than a packet in each case checked completely for correctness at the receiving end.

In order to identify the subpackets received without errors, the completely received packets can, as already mentioned, be stored successively in the receiver and their subpackets assigned to one another can in each case be examined. Corresponding subpackets of this type which now occur as matching are deemed to be correctly received, since the probability that bits assigned to one another in the short subpackets have been subjected to the same interference is sufficiently low. If the combined correct subpackets then produce a complete receive packet once more, the latter will be interference-free.

The subpacket-based checking according to the invention can be carried out even more quickly if the packet is already subdivided into subpackets at the transmitting end and an error detection code is assigned to each individual subpacket. An error detection code of this type may contain a CRC checksum or, for example, as implemented in the WMBUS, a 3-from-6 coding.

A subpacket can also be provided with a plurality of error detection facilities simultaneously, e.g. with a plurality of connected 3-from-6 codings or with a plurality of CRC checksums. In each case, from successively received packets, only their correctly received subpackets need to be temporarily stored in each case until they have been finally assembled in a gap-filling manner into a correct receive packet.

If subpackets provided with at least one error detection code are received as errored at the transmitting end, they do not, however, have to be rejected. The two aforementioned variants can instead be combined with one another in the sense that the errored subpacket for its part—and also the corresponding subpacket of at least the following packet used for the comparison—is divided into secondary subpackets. Only one of these will be errored, and the others can already be inserted into the still open error position in the receive packet. Subdivision of this type can be scaled to greater depth in order to exploit usable packet parts.

One application of subdivision of this type to successively correctly received subpackets results in a desirable improvement in the residual error probability.

In each case, from the packets received multiple times successively with interference, their correctly received subpackets are therefore extracted, temporarily stored and finally compiled into an interference-free receive packet, dispensing with a conventional assessment of the received packets in their entirety. It is therefore no longer significant if two successive packets do not match one another and should therefore actually be rejected, but instead, from each of these unusable packets, their usable subpackets are now extracted in order to assemble an interference-free receive packet from them. This is achieved more quickly than by waiting for entire packets received totally without error, thus saving energy-related and channel-specific resources since the original packets have to be transmitted less frequently in order to achieve a usably available receive packet. The longer the original information message (i.e. the packet), the greater the advantage of the compilation according to the invention of the receive packet from subpackets received without error, since the risk of interference increases with the packet length; for which reason very long packets in the conventional complete evaluation have virtually no chance of being able to be transmitted via one of the severely interference-affected channels.

An improvement in the probability of success in respect of a usably available receive packet—and therefore the system QoS (matching of the quality of the communication service in a given interference environment with the requirements of the user)—by at least 20% is mathematically provable.

Additional developments of the solution according to the invention and its alternatives can be found in the further claims and, also taking account of their advantages, from the description below of preferred implementations of the invention, In the drawing, by way of example and restricted to symbolic drawings with, for illustrative purposes, unrealistically few transmission repetitions and subpackets, based on the example of a one-way radio link:

Other features which are considered as characteristic for the invention are set forth in the appended claims.

Although the invention is illustrated and described herein as embodied in a method for transmitting information, it is nevertheless not intended to be limited to the details shown, since various modifications and structural changes may be made therein without departing from the spirit of the invention and within the scope and range of equivalents of the claims.

The construction and method of operation of the invention, however, together with additional objects and advantages thereof will be best understood from the following description of specific embodiments when read in connection with the accompanying drawings.

### BRIEF DESCRIPTION OF THE SEVERAL VIEWS OF THE DRAWING

FIG. 1 is an illustration showing an information transmission with subpacket formations on repeatedly received packets only at a receiving end; and

FIG. 2 is an illustration showing an information transmission with subpacket formation already at a transmitting end.

### DETAILED DESCRIPTION OF THE INVENTION

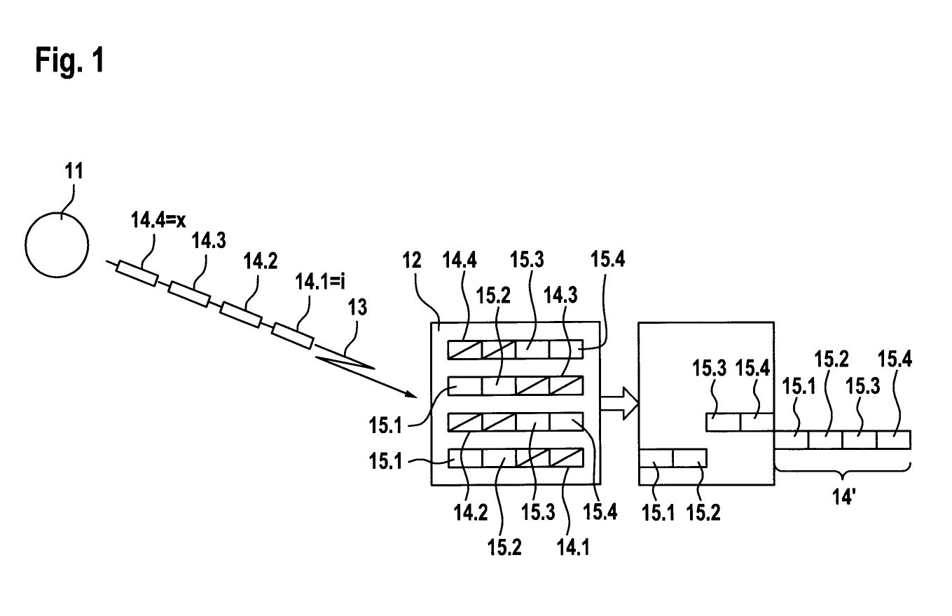

Referring now to the figures of the drawings in detail and first, particularly to FIG. 1 thereof, there is shown a normally battery-operated transmitter 11 that is, for example, a control unit of a radio remote control for domestic appliances, but, in particular, a consumption metering point (smart meter) which sporadically or more or less continuously transmits current or accumulated measured values.

A receiver 12 may correspondingly be a switching device for a drive device in situ, or a concentrator for the temporary storage and, if necessary, processing of measured values which, correspondingly source-coded, can also be received from a plurality of different metering points. It may equally also be a radio link 13 from a concentrator equipped with a transmitter to a receiver at an addressed metering point, for example to transmit tariff change information. In practice, it predominantly involves two-way radio links of this type between a concentrator and a number of metering points.

The information transmission, drawn by way of example as a one-way transmission, from the transmitter 11 to the receiver 12 is performed successively in packets via a radio link 13 in one of the ISM bands freely available for this purpose, but correspondingly under a heavy load and severely affected by interference. The repeatedly transmitted information is in each case coded, for example as a binary sequence to form a packet 14.i which is 64 bytes long.

Even if only one bit of the received packet 14.i is affected by interference, the information will be lost. Each packet 14.i is therefore transmitted i=x times. For the communication to be successful at least two successive repetitions of the x repetitions must conventionally be totally free from interference, i.e. they must have been received as exact matches. The resulting transmission outlay is therefore considerable, since successively received complete packets 14 must in each case be compared with one another and, if necessary, rejected.

Conversely, as already mentioned above, the invention is based on the notion that only a part of the received packet 14 is in fact normally affected by interference, whereas the interference-free part corresponds exactly to the transmitted bit sequence.

In the variant according to the invention shown in FIG. 1, each received packet 14.i is therefore divided into subpackets 15.j=y and is temporarily stored in the receiver 12. Packets 14.i are received successively for this purpose. Subpackets 15.j allocated to one another therein are compared with one another and are deemed to be correct, i.e. to be received without interference, if at least two of them match one another. If all received subpackets 15.j=y) are therefore detected as valid, they are assembled into the interference-free receive packet 14′.

The subpackets 15.j within the packets 14.i can essentially be of different lengths, and their length may also vary. In order to simplify the presentation, the drawing shows subpackets 15 of equal length, for example (typically at least) j=y=4 subpackets 15.j, each comprising 16 bytes, of a packet 14.i which is 64 bytes long. The probability of transmitting a long subpacket 15 without interference is generally lower than in the case of a shorter subpacket 15 due to the longer-lasting potential effects of interference. Shorter (but not too short) subpackets 15.j therefore offer increased probabilities in terms of the existence of interference-free subpackets 15.j.

In the example embodiment shown in FIG. 1, x=i=4 successive complete packets 14.i having identical content are received and temporarily stored in the receiver 12. Those of the at least two subpackets 15.j which are assigned to one another on the basis of their respective position in the packet 14,i and which specifically have at least two instances of matching content (here 15.1 in 14.1 and 14.3; 15.2 in 14.1 and 14.3; 15.3 in 14.2 and 14.4; 15.4 in 14.2 and 14.4) are deemed to be received without interference and are therefore assembled in a gap-filling manner into the valid, since interference-free, receive packet 14′. A packet 14′ is therefore available at the receiver 12 more quickly than in the case of waiting until at least one entire packet repetition matches.

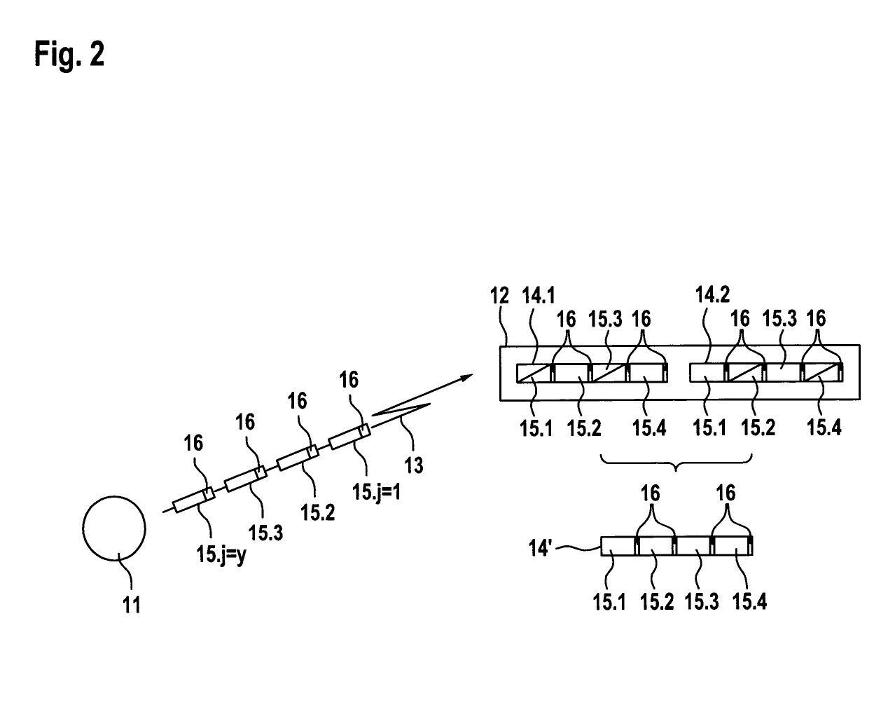

A valid, since interference-free, receive packet 14′ is even more quickly available if the respective subpacket 14.i is already divided into subpackets 15.j (j=1 . . . y) at the transmitting end according to the development shown in FIG. 2. In order to establish whether these received subpackets 15.j are in each case valid, their bit sequence is checked for correctness at the receiving end. To do this, an error detection code 16, e.g. a CRC checksum, is already attached at the transmitting end in a manner known per se to each of these subpackets 15.i.

For the example drawing, the subdivision into subpackets 15.j is in turn assumed to be identical in all packets 14.i without them having to be intrinsically identical; i.e. again as a subdivision of the 64-byte-long packet 14.i in each case into four equal-length subpackets 15.y=4, each containing 16 bytes.

Each received subpacket 15.j of a packet 14.i just received can be rejected immediately in the receiver 12 if the error detection code 16 detects a transmission error in this subpacket 15.j; here in the packet 14.i=1 in the case of the subpackets 15.j=1 and 15.3 and also in the following packet 14.2 in the case of the subpackets 15.2 and 15.4. The gaps still remaining in the packet 14′ at the receiving end when the first packet 14.1 is received are filled from the next (or, if necessary, the next-but-one, etc.) received packet 14.i in which precisely this still missing packet 15.j is not affected by interference; as a result of which the interference-free packet 14′ is then already available in assembled form.

Instead of or in addition to the error detection 16, it can also be demanded, comparable to the method according to FIG. 1, that, in the case of more than two transmissions, the subpackets 15.j received in succession and compared with one another match one another in order to classify them as valid. This results in an increased reliability of the received data.

In another advantageous combination of both described measures, the subpackets 15.j detected as usable via error detection codes 16 according to FIG. 2 are in turn divided into secondary subpackets at the receiving end and are selected in the reciprocal comparison according to FIG. 1. This improves the residual error probability.

In one development according to the invention, it is also possible to combine the two measures outlined in relation to FIG. 1 or FIG. 2 in the sense that not only the subpackets 15.j proven to be usable via error detection codes 16 according to FIG. 2, but also the unusable subpackets are stored. Usable subpackets can then be extracted from the latter through the subdivision in the reciprocal comparison according to FIG. 1.

If different error detection methods are combined in such a way, for example, a CRC checksum investigation can first be carried out. Subpackets 15.j thus detected as an error, divided into secondary subpackets, can be investigated by means of a different checksum, for example a 3-from-6 coding, and can be reconstructed.

In the repeated transmission of information in the form of a coded packet 14.i from a transmitter 11 via a potentially interference-affected radio link 13 to a receiver 12 which is operated, in particular, in the concentrator of a recording system for consumption measured values, the interference-free receive packet 14′ is therefore available comparatively quickly if interference-free received subpackets 15.j are assembled according to the invention into the interference-free receive packet 14′. For this purpose, successively received packets 14,i can be temporarily stored in the receiver 12 in order to compare subpackets 15.j assigned to one another therein and, in the event of a match, to assemble them in a gap-filling manner into the interference-free receive packet 14′, Alternatively, the successive packets 14.i are already divided in each case at the transmitting end into subpackets 15.j provided with error detection codes 16, the subpackets being assembled in a gap-filling manner into the interference-free receive packet 14′ if they have been correctly received.

1. A method for transmitting information in a form of a coded packet, which comprises the steps of:
transmitting repeatedly the coded packet from a transmitter via a radio link to a receiver; and
assembling interference-free subpackets derived from received coded packets into an interference-free received packet.

2. The method according to claim 1, which further comprises dividing the coded packet transmitted multiple times in succession at a receiving end into the subpackets.

3. The method according to claim 1, which further comprises dividing the coded packet transmitted multiple times in succession at a receiving end into the subpackets provided with error detection codes.

4. The method according to claim 1, wherein lengths of the subpackets are statically or dynamically variable.

5. The method according to claim 2, which further comprises:
comparing the subpackets of successively received coded packets assigned to one another at the receiving end on a basis of an arrangement in the coded packet with one another; and
assembling the subpackets into the interference-free received packet in an event of a match.

6. The method according to claim 1, wherein at least x=3 successively received coded packets are in each case divided into a sequence of at least y=3 said subpackets.

7. The method according to claim 2, which further comprises dividing the subpackets into secondary subpackets which are to be compared with one another.

8. The method according to claim 3, which further comprises comparing the subpackets successively received correctly according to an error detection code with one another for matching.

9. The method according to claim 3, which further comprises dividing the subpackets received into secondary subpackets which are to be compared with one another.

10. The method according to claim 3, which further comprises providing the subpackets at a transmitting end with cyclic redundancy check (CRC) checksums, with 3-from-6 codings or with different or with a plurality of error detection codes.
